(19) United States
(12) Patent Application Publication
(10) Pub. No.: US 2007/0023765 A1
(43) Pub. Date: Feb. 1, 2007

(54) Acicular ITO for LED array

(76) Inventors: Alan C. Thomas, Gilbert, AZ (US); Ilona Budinavicius, Phoenix, AZ (US); Walter J. Paciorek, Phoenix, AZ (US)

Correspondence Address: Paul F. Wille;Cantor Colburn LLP, 55 Griffin Road South, Bloomfield, CT, 06002, US

(21) Appl. No.: 11/193,305

(22) Filed: Jul. 29, 2005

(51) Int. Cl. H01L 27/15

(52) U.S. Cl. 257/81

(57) ABSTRACT

In an array of LEDs coupled between a transparent substrate and an electrode, a light emitting surface of each LED is in electrical contact with a region of acicular ITO. By contacting the light emitting surface of the die, the acicular ITO also provides light scattering. The contact regions are interconnected to form the array. The acicular ITO acts as a ballast resistance for each die and the resistance can be trimmed for more uniform current among the LEDs. Because each LED is individually ballasted, the LEDs in an array can be driven in any pattern or all simultaneously at a consistent brightness.

### FIELD OF THE INVENTION

This invention relates to light sources or displays utilizing an array of light emitting diodes (LEDs) and, in particular, to improving the uniformity of light emission from an array of LEDs.

### GLOSSARY

“Point” is not used in the mathematical sense of vanishingly small. A point source of light is a bright source in a small, finite space, “small” being relative to the size of the surrounding structure. Some people may quibble that a point source of light radiates uniformly in all directions. That quibble is not true in practice and does not apply here. As such, incandescent lamps, LEDs, some gas discharge lamps, and others are point sources of light even though, as in the case of LEDs, they radiate in a preferred direction.

Strictly speaking, all non-luminous objects, except black holes, reflect light, otherwise nothing would be visible. A reflecting surface is either specular (a mirror-like or polished surface), uniformly diffuse, or somewhere in-between. At a microscopic level, even a highly polished, front surface mirror is not perfectly specular, nor is any diffuse reflector perfectly lambertian. Mathematical minutiae are of no concern here. Rather the concern is with a macroscopic, practical, diffuser that is reasonably, if not perfectly, lambertian. Many objects fulfill this criterion, such as particles dispersed in a medium, a sheet of white paper, or a sheet of white plastic. Obviously, colored paper or plastic filters the light in addition to reflecting the light.

A “luminous” object emits light. Light incident upon a subject “illuminates” the subject. “Luminance” refers to the amount of light emitted from a source. “Illuminance” refers to the amount of light incident upon a subject.

A “graphic” can be text, a symbol, an arbitrary shape, or some combination thereof. A graphic can be translucent, shaded, colored, a silhouette or outline, or some combination thereof.

As used herein, a “flex circuit” is any type of substrate including conductive traces for including LEDs and other devices in an electrical circuit. As such, a flex circuit includes printed circuit boards. The flexibility of the substrate has no bearing on the invention.

An “LED” is a semiconductor die that has a p-n junction that emits light from at least one surface of the die when the junction is forward biased.

### BACKGROUND OF THE INVENTION

It is known in the unrelated art of astronomy to make a flat field projector by sandblasting an aluminum plate and illuminating the plate with four LEDs; see Simon Tulloch, Design and Use of a Novel Flat Field Illumination Light Source, Technical Note 108, Instrument Science Group, Royal Greenwich Observatory, 1996.

For back lighting, display, and other applications, one wants as uniform a light source as possible, and therein lies a problem. LEDs have numerous advantages over incandescent lamps but, like incandescent lamps, are point sources of light. Various forms of light guides or light channels are used to diffuse the light but the fact remains that a point source of light is often visible through the object being backlit. A result is non-uniform lighting. Light from a source that is viewed directly is “glare” and is undesirable. The need for light guides and the like requires complex structures that are expensive to manufacture, at least for initial tooling.

Arrays of LEDs have long been known in the art. For example, U.S. Pat. No. 4,047,075 (Schoberl) discloses an array of LEDs made by simply stacking a plurality of packaged LEDs in a small volume. Packaged LEDs occupy considerably more volume than the semiconductor die or chip within the package. U.S. Pat. No. 4,335,501 (Wickenden et al.) discloses an array of LED dice on a single semiconductor substrate.

An LED is a non-linear device. Like most diodes, an LED does not conduct until a forward bias exceeds a threshold, e.g. 0.6 volts, and then conduction must be limited by some sort of ballast, typically a series resistance. Current is typically 10-60 ma. and brightness is roughly proportional to current. The color of the emitted light may also change with changes in current. As with any device, LEDs produce heat. Unfortunately, LEDs typically have a negative temperature coefficient of resistance, which means that current increases with temperature. Thus, controlling current is important for several reasons.

Two LEDs of the same type number do not necessarily have the same electrical characteristics. If a single resistor is used for ballast for two parallel LEDs, then the failure of one LED can result in the second LED being overdriven (too much current) and, consequently, failing soon thereafter. Larger arrays, with LEDs in series and in parallel have the same problem, only compounded by a greater number of LEDs. Although it is separately well known in the art that current through an LED must be carefully controlled, many of the patents on arrays of LEDs have a paucity of disclosure on how to drive the array, except to limit or to “condition” current in some undisclosed manner. It may be that uniform brightness is not a concern or is too difficult to achieve in the disclosed configurations.

The use of reflection and diffusion to enhance the uniformity of light emitted from an LED and, particularly, from an array of LEDs, is known in the art; e.g. the Schoberl patent identified above. Providing such means for an unpackaged die is a much more difficult proposition, if for no other reason than the die or chip is relatively unprotected. Moreover, the die is a crystal of two or more elements (ignoring trace amounts of dopants), e.g. gallium arsenide or indium gallium nitride, which is more fragile than silicon. The metallurgy for contact areas further increases stress within a die. Thus, handling LED dice must be done much more delicately than for packaged devices.

For example, for LED dice mounted on a flexible substrate, the front electrode of each die is wire bonded to a gold contact on the die. The die is encapsulated to protect the wire bond and the die is pushed into a transparent conductive layer to make contact. The conductive layer is a sputtered indium-tin-oxide (ITO) layer or ITO powder in a suitable binder. A polymeric, conductive layer of PEDOT-PSS (poly-3,4-ethylenedioxythiophene/polystyrenesulfonic acid) may be used instead. Despite the relative flexibility of the substrate and the other layers, die are often cracked while assembling an array. In addition, the wire bonding and coating are expensive.

A material referred to as acicular ITO is known in the art as a transparent conductor; see U.S. Pat. No. 5,580,496 (Yukinobu et al.) and the divisional patents based thereon (U.S. Pat. Nos. 5,820,843, 5,833,941, 5,849,221). Acicular ITO has a fibrous structure composed of 2-5 μm thick by 15-25 μm long ITO needles. The needles are suspended in an organic resin, e.g. polyester. Acicular ITO is different in kind from other forms of the material. A cured, screen printed layer of acicular ITO is approximately five times more conductive than conventional layers containing ITO powder but is about two thirds less conductive than sputtered ITO, which is more difficult to pattern than screen printable materials.

In view of the foregoing, it is therefore an object of the invention to provide an array of LEDs wherein each LED can be ballasted individually.

Another object of the invention is to provide an array of LEDs that is less expensive to manufacture than arrays of the prior art.

A further object of the invention is to improve the reliability of the contacts to an LED in an array, particularly a flexible array;

Another object of the invention is to provide an array of LEDs in which light emission is made more uniform by diffusion in a transparent electrode layer, obviating the need for a separate diffusing layer.

A further object of the invention is to provide an array of LEDs that has a ballast resistance integral with each LED.

Another object of the invention is to provide an array of LEDs in which a ballast resistance for each LED can be adjusted individually to provide more uniform current and more uniform brightness.

A further object of the invention is to provide an array of LEDs that are substantially uniformly bright when lit.

Another object of the invention is to provide an array of LEDs that are substantially uniformly bright when lit, either simultaneously or in subsets of the entire array.

A further object of the invention is to provide an array of LEDs in which the failure of one LED has substantially no effect the brightness of other LEDs in the array.

### SUMMARY OF THE INVENTION

The foregoing objects are achieved in this invention wherein, in an array of LEDs coupled between a transparent substrate and an electrode, a light emitting surface of each LED is in electrical contact with a region of acicular ITO. By contacting the light emitting surface of the die, the acicular ITO also provides light scattering. The contact regions are interconnected to form the array. The acicular ITO acts as a ballast resistance for each die and the resistance can be trimmed for more uniform current among the LEDs. Because each LED is individually ballasted, the LEDs in an array can be driven in any pattern or all simultaneously at a consistent brightness.

### BRIEF DESCRIPTION OF THE DRAWINGS

A more complete understanding of the invention can be obtained by considering the following detailed description in conjunction with the accompanying drawings, in which:

FIG. 1 is a cross-section of a single LED in an array constructed in accordance with a preferred embodiment of the invention;

FIG. 2 is a plan view of a portion of the array illustrated in FIG. 1;

FIG. 3 illustrates adjusting the resistance of the ballast in accordance with one aspect of the invention;

FIG. 4 illustrates adjusting the resistance of the ballast in accordance with another aspect of the invention;

FIG. 5 is a schematic of an array of LEDs constructed in accordance with the invention;

FIG. 6 is a cross-section of a single LED in an array constructed in accordance with an alternative embodiment of the invention;

FIG. 7 is a cross-section of a single LED in an array constructed in accordance with an alternative embodiment of the invention;

FIG. 8 is a cross-section of a single LED in an array constructed in accordance with an alternative embodiment of the invention; and

FIG. 9 is a cross-section of a single LED in an array constructed in accordance with another aspect of the invention;

### DETAILED DESCRIPTION OF THE INVENTION

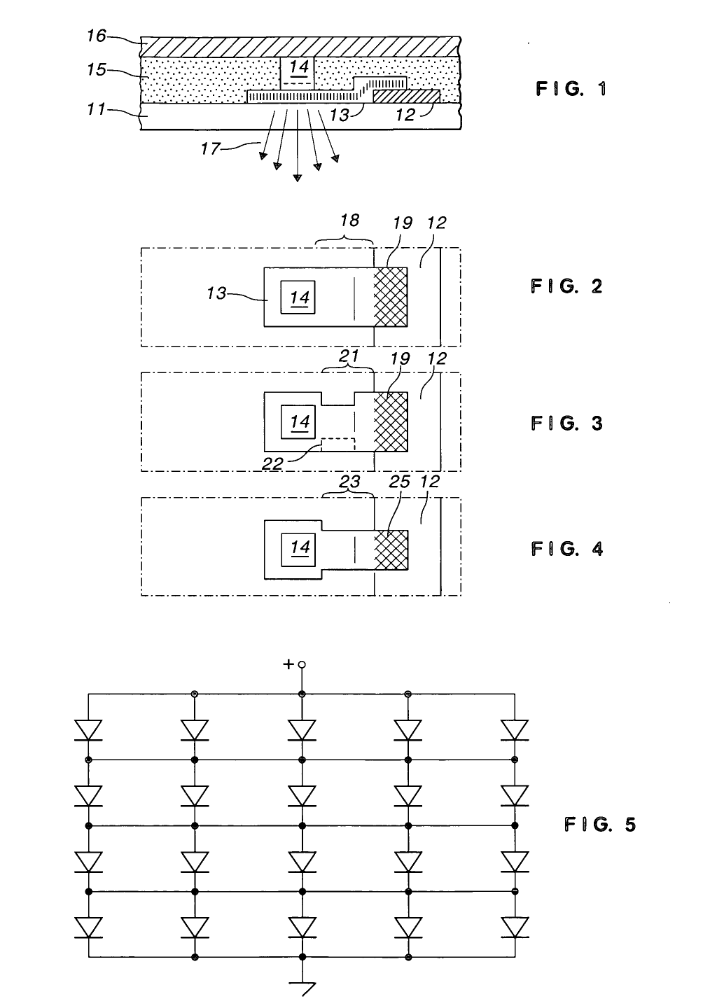

FIG. 1 illustrates in cross-section a single member of an array of LEDs. The array is supported on transparent polymer substrate 11 having a thickness of 0.08 mm to 0.18 mm. Bus bar 12 extends into the plane of the drawing, connecting a plurality of LEDs in a row. Bus bar 12 is preferably screen printed from a silver bearing ink, although other conductive particles can be used instead, e.g. carbon. Acicular ITO region 13 is screen printed on substrate 11 and bus bar 12. Region 13 preferably provides a contact area for a single LED. LED 14 is placed on region 13 and emits light predominantly downwardly through the acicular ITO, as indicated by arrows 17. The fibrous particles of acicular ITO act as diffusers, spreading the light from die 14. Adhesive layer 15 electrically isolates ITO layer 13 and bus bar 12 from rear electrode 16, which is preferably a layer of aluminum.

The array is assembled in the order described above, except that adhesive layer 15 is applied before placing LED 14. Layer 15 is soft and LED 14 is pushed through the layer to contact acicular ITO layer 13. Adhesive layer 15 is preferably a heat activated adhesive, although a UV (ultraviolet light) activated adhesive can be used instead. Layer 15 is heated, e.g. to approximately 80° C., to join the layers after assembly.

As thus constructed, current flowing from the rear electrode through the LED also flows through the acicular ITO to bus bar 12. Region 13 thus provides an individual, series resistance that can be adjusted by changing the geometry of the region. The acicular ITO region acts as a contact, an interconnect, and a series resistance. The resistance is part of a flat thin device that occupies very little horizontal area beyond the area of the die and requires no external components, which would be unwieldy and expensive.

As illustrated in FIG. 2, section 18 of acicular ITO layer 13 interconnects the area under die 14 and area 19 of overlap with bus bar 12. The geometry of section 18 can be changed to change resistance. Area 19 is sufficient to provide a reliable, low resistance connection between layer 13 and bus bar 12. The series resistance of the interconnection is largely determined by the shape of section 18 between die 14 and bus bar 12.

In FIG. 3, section 21 is reduced in width or constricted to increase series resistance. The constriction can take place from one edge or from both edges of section 21, as indicated by dashed line 22. The edges of the constriction need not be rectangular or any particular shape. A rectangular shape is illustrated for convenience.

In FIG. 4, section 23 and area 25 are both reduced. Thus, the series resistance of acicular ITO section 23 is higher than the series resistance of acicular ITO section 21, which, in turn, is higher than the series resistance of acicular ITO section 18.

It is undesirable to reduce the contact area underneath die 14 because one wants the best possible electrical and thermal contact with the die. The acicular ITO layer is shown surrounding die 14, which is preferable to provide a margin of error when placing the die in an array. Current does not flow through the margin, only between the die and the bus bar. Thus, the margin has substantially no effect on resistance.

The resistance is preferably adjusted by laser trimming, which can be done during assembly or through transparent substrate 11 after assembly. Alternatively, each LED can be tested while in transit to the array and preselected for the particular pattern screen printed for region 13.

FIG. 5 illustrates an array of LEDs, wherein each LED includes a series resistor in accordance with the invention. It is presumed that LEDs fail by becoming open circuits rather than short circuits. If the array is driven from a constant current source and one diode fails, the remaining diodes in the same row will pass slightly greater current but the change is much less than without individual series resistances. If the array is driven from a constant voltage source, the failure of a single LED slightly diminishes the current in the rows other than the row of the failed LED but the change is much less than without individual series resistances.

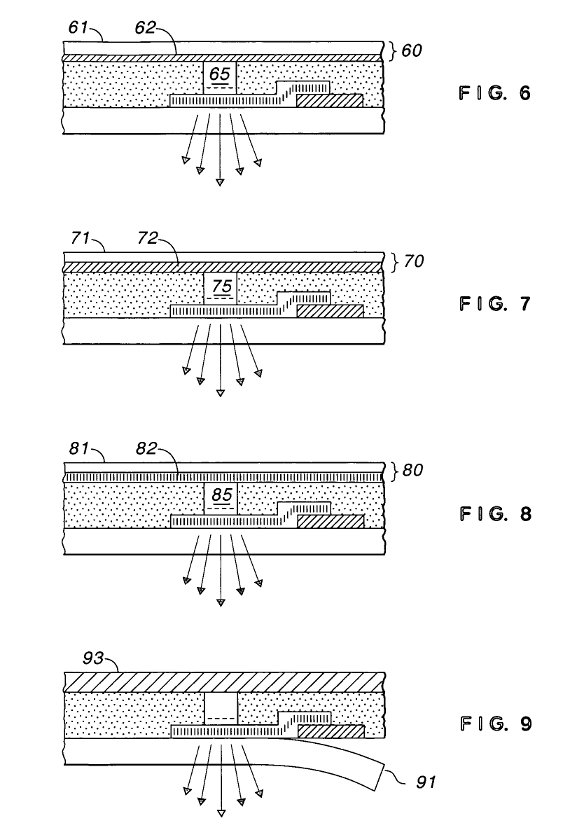

FIG. 6 illustrates in cross-section a single member of an array of LEDs constructed in accordance with an alternative embodiment of the invention. In particular, FIG. 6 differs from the embodiment of FIG. 1 in that rear electrode 60 includes plastic film 61, which may be opaque or transparent, and ITO layer 62, which is preferably sputter deposited upon film 61. This embodiment operates in the same manner as the embodiment of FIG. 1, except that LED 65 can be placed to emit predominantly upwardly, as oriented in the figure, rather than downwardly as shown.

FIG. 7 illustrates in cross-section a single member of an array of LEDs constructed in accordance with an alternative embodiment of the invention. In particular, FIG. 6 differs from the embodiment of FIG. 1 in that rear electrode 70 includes plastic film 71, which may be opaque or transparent, and screen printed, conductive layer 72. Layer 72 is preferably patterned and includes silver bus bars. This embodiment operates in the same manner as the embodiment of FIG. 1, except that LED 75 can be placed to emit predominantly upwardly, as oriented in the figure, rather than downwardly as shown.

FIG. 8 illustrates in cross-section a single member of an array of LEDs constructed in accordance with an alternative embodiment of the invention. In particular, FIG. 6 differs from the embodiment of FIG. 1 in that rear electrode 80 includes plastic film 81, which may be opaque or transparent, and acicular ITO layer 82. Layer 82 is preferably patterned to reduce consumption of ink and reduce cost. This embodiment operates in the same manner as the embodiment of FIG. 1, except that LED 85 can be placed to emit predominantly upwardly, as oriented in the figure, rather than downwardly as shown.

FIG. 9 illustrates in cross-section a single member of an array of LEDs constructed in accordance with another aspect of the invention. In particular, FIG. 9 differs from the embodiment of FIG. 1 in that substrate 91 is peeled away, leaving rear electrode 93 for structural support. A release layer (not shown) can be added to facilitate separation. Rear electrode 93 is a conductive sheet, such as copper or aluminum, as described above, or a flex circuit, or other material that is sufficiently dimensionally stable to support the array. This embodiment operates in the same manner as the embodiment of FIG. 1. This aspect of the invention can be combined with any of the embodiments described above.

The invention thus provides an array of LEDs wherein each LED can be ballasted individually with a ballast resistance integral with each LED to provide an array in which the failure of one LED has substantially no effect the brightness of other LEDs in the array. The individual ballast resistances can be adjusted to provide more uniform current and more uniform brightness. The array is less expensive to manufacture than arrays of the prior art and the reliability of the contacts to an LED is improved. Light emission is made more uniform by diffusion in a transparent electrode layer, obviating the need for a separate diffusing layer. The LEDs that are substantially uniformly bright when lit, either simultaneously or in subsets of the array.

Having thus described the invention, it will be apparent to those of skill in the art that various modifications can be made within the scope of the invention. For example, bus bar 12 can be printed after, i.e. on, acicular ITO region 13, rather than before. Rear electrode 16 can be any high conductivity material. Aluminum is preferred because it is the most cost effective. FIG. 5 illustrates an array in which the LEDs are lit simultaneously. Switches (not shown) can be added to provide lighting in any desired pattern. By addressing individual LEDs, the LEDs are, electrically, all in parallel in one great row (or column), although they appear arranged in rows and columns. When in parallel, the failure of one LED has no effect on the remainder when fed with constant voltage. One could use abrasion or etching for adjusting resistance. Although either could provide a three dimensional change in geometry, adjusting thickness as well as shape, neither is as precise or as efficient as ablation with a laser. Although acicular ITO is the preferred material, other fibrous or whisker-like material having similar resistivity can be used instead. For example, carbon nanotubes can be used if their light absorption properties can be tolerated. Other conductive whisker materials include ZnO-based compositions, such as ZnO:Al or ZnO:Ga.

What is claimed as the invention is:

1. In an array of LEDs coupled between a transparent substrate and an electrode, the improvement comprising:
a region of acicular ITO between at least one LED and the transparent substrate for electrically coupling to the light emitting surface of the LED.

2. The array as set forth in claim 1 wherein each LED in the array is coupled to the substrate by a region of acicular ITO, thereby individually ballasting each LED in the array.

3. The array as set forth in claim 2 wherein the regions of acicular ITO are electrically coupled together to provide simultaneous light emission from all LEDs in the array.

4. The array as set forth in claim 3 wherein groups of LEDs are coupled in parallel in rows and the rows are coupled in series.

5. The array as set forth in claim 2 wherein at least two regions are coupled to a bus bar by a section of acicular ITO.

6. The array as set forth in claim 5 wherein the area of a first section is not equal to the area of a second section.

7. A light emitting device comprising:
a semiconductive die having a junction that emits light through a surface of the die when the junction is forward biased;
a layer of acicular ITO on said surface.

8. A method for making an array of light emitting diodes, said method comprising the steps of:
forming a plurality of conductive areas on a substrate, wherein each conductive area is acicular ITO;
attaching an LED on each conductive area; and
positioning each LED in such a way that a light emitting surface of the LED is in contact with the acicular ITO.

9. The method as set forth in claim 8 and further including the steps of:
forming a bus bar on the substrate; and
forming the conductive areas partially overlapping the bus bar.

10. In an array of LEDs, each including a p-n junction and a conductor for supplying current to at least one p-n junction, the improvement comprising:
a region of acicular ITO between one side of at least one p-n junction and said conductor for electrically coupling the p-n junction to the conductor.

11. The array set forth in claim 10 wherein the region provides a ballasting load for said p-n junction.

12. The array as set forth in claim 11 wherein the area of said region can be adjusted to vary the load for said p-n junction.
